(19) United States
(12) Patent Application Publication
(10) Pub. No.: US 2017/0162559 A1
(43) Pub. Date: Jun. 8, 2017

(54) INTEGRATED VERTICAL SHARP TRANSISTOR AND FABRICATION METHOD THEREOF

(71) Applicant: Dumitru Nicolae Lesenco, Austin, TX (US)

(72) Inventor: Dumitru Nicolae Lesenco, Austin, TX (US)

(21) Appl. No.: 14/961,317

(22) Filed: Dec. 7, 2015

(51) Int. Cl. H01L 27/06; H01L 29/16; H01L 29/06; H01L 21/8249; H01L 29/423; H01L 29/10; H01L 21/8238; H01L 27/092; H01L 29/78; H01L 29/08

(52) U.S. Cl. CPC H01L 27/0623; H01L 29/7827; H01L 29/16; H01L 29/0657; H01L 29/0692; H01L 29/0847; H01L 29/42376; H01L 29/0804; H01L 29/0821; H01L 29/1004; H01L 21/823885; H01L 27/092; H01L 21/8249

(57) ABSTRACT

The present invention relates to vertical integrated, quantized FET with sharp drain and BJT with sharp emitter implemented in one nano-BiCMOS process, using multiple identical single crystalline semiconductor pyramids, placed in-situ directly on the surface of diffusion regions. The devices' gate and base structures are formed at a level of 35-45 nm below the top of the pyramids. The bottom region of the pyramids contains the collector/source structures, while the top region of the pyramids contains the emitter/drain structures. The base structure for BJT is formed by selective epitaxial growth of Si—SiₓGe₁₋ₓ—Si with opposite conductivity type as COR, and interconnected by a horizontal polysilicon grid. The self-aligned gate structure for FET is formed by high dopant implantation of impurity with the same type of conductivity as COR through horizontal gate bridge, which represent a grid of horizontal stacked layers Si₃N₄ —high-k insulator—polysilicon—high-k insulator—Si₃N₄.

### REFERENCE CITED

### Patent Citations

[1]. U.S. Pat. No. 6,885,055 B2 Double-gate FinFET device and fabricating method thereof Apr. 26, 2005 Jong-Ho Lee . . . 257/618.

[2]. U.S. Pat. No. 7,736,979 B2 Method of forming nanotube vertical field effect transistor, Jun. 15, 2010, Reginald Conway Farrow et al.

[3]. U.S. Pat. No. 7,625,792 B2 Method of base formation in a BiCMOS process, Dec. 1, 2009, Peter J. Geiss et al.

[4]. U.S. Pat. No. 4,96,0726 BI CMOS Process, Oct. 2, 1990, John S. Leachaton et al. U.S.Cl. 437/59.

[5]. U.S. Pat. No. 7,384,835 B2 MOSFET with a sharp halo and a method of forming the transistor, Jun. 10, 2008. Haujie Chen et al U.S.Cl. 438/197.

[6]. U.S. Pat. No. 7,625,792 B2 Method of base formation in a BICMOS process, Dec. 1, 2009. Peter J. Geiss et al U.S.Cl. 438/202

[7]. U.S. Pat. No. 6,774,000 B2 Method of manufacturing of MOSFET device with in-situ doped, raised source and drain structures, Aug. 10, 2004, Wesley C. Natzle et al. U.S.Cl. 438/202.

[8]. U.S. 20050093084 A1 Ultra-shallow junction MOSFET having a high-k gate dielectric and in-situ doped selective epitaxy source/drain extensions and a method of making same, Mai 2005, Chih-Hao Wang et al

[9]. U.S. Pat. No. 6,53,1325 B1 Memory transistor and method of fabricating same, Mar. 11, 2003, Sheng Teng Hsu et al U.S.Cl. 438/3.

[10]. U.S. Pat. No. 8,758,850 B2 STTMRAM MTJ manufacturing method with in-situ annealing, Jun. 24, 2014, Yuchen Zbou et al. U.S.Cl. 427/130

### Non-Patent Citations

[11]. Anisotropic Trench Etching of Silicon with High Aspect Ratio and Aperture of 30-50 nm in a Two-Stage Plasma-Chemical Cyclic Process, by S. N. Averkin et al. Jul. 15, 2014

[12]. www.oxford-instruments.com Silicon Cryogenic Etching results for Si Fin (100).

[13]. www.dmse.nus.edu.sg Pencil texture Silicon (111).

[14]. www.sentech.com Plasma cryogenic Si, Plasma lithography, Plasma PhC SI591 anisotropic Etch lab microstructures.

[15]. Fabrication of high-aspect-ratio silicon nanostructures using near-field scanning optical lithography and silicon anisotropic wet-etching process. S. J. Kwon et al. Appl. Phys. A86, 1118 (2007)

### BACKGROUND

1. Field of the Invention

The present invention relates to vertical integrated quantized semiconductor sharp devices and fabrication methods thereof, using conventional BiCMOS process, adjusted to quasi-planar procedures. More particularly, the invention relates to FET with sharp drain and BJT with sharp emitter implemented into multiple identical single crystalline semiconductor pyramids, placed in-situ directly on the surface of diffusion regions with high dopant level of a first and second conductivity type, formed respectively in the wells. In disclosed embodiment the devices gate and base structures are formed below of the tip of pyramids on range about 35-45 nm. In the bottom region of pyramids are formed collector/source structures, and in the top region—emitter/drain structures. The pyramids are obtained by selective epitaxial growing of low dopant Si (100) into cavities formed in oxide layer. The size of pyramids is around 60×60×120 nm with 120 nm pitch. After growing, a COR pre-clean (sharpening) is performed and the recesses are filled by epitaxial growing of a low dopant layer of a same conductivity type and dopant level as COR. Than the pyramid structures for BJT are selective high doped and formed collector structure of a first and second conductivity type. The base structure is formed by selective epitaxial growing of Si—SiₓGe₁₋ₓ—Si with opposite conductivity as COR, and interconnected by horizontal polysilicon layer. The self-aligned gate structure for FET is formed by high dopant implantation of impurity with the same type of conductivity as COR through horizontal gate bridge, which represent a grid of horizontal layers Si₃N₄—high-k insulator—polysilicon—high-k insulator—Si₃N₄. The grid coupled a plurality of pyramids, formed one quantized transistor. The oxide under the bridge is etched, then the pyramid structures for FET are selective high doped and formed gate structure of a first and second conductivity type.

2. Description of the Related Art

Worldwide researches are actively being undertaken in the area of nano-CMOS and bipolar device technologies since the applications in logic, analog and memories circuits have the capability of creating substantial value added revenues. The system based on the silicon semiconductor technology is becoming smaller and requires low electric power consumption and high speed operation. The size of its devices should be small accordingly, but the impact of various parasitic effects became critical.

Double-gate FinFET devices and fabrication methods thereof using Silicon On Insulator (SOI) substrate with the focus on realizing a device with the channel length below 28 nm., is described in [1], which can be take in consideration as an analog to present disclosure. (FIG. 4.b).

In general, FinFET technology has a large application in semiconductor industry for technological nodes 28, 16, 14, 10 and 6 nm. However, FinFET technology does not allow implementation of bipolar transistors in one chip, like BiCMOS in 65 nm. technology. Layout is similar to conventional MOSFET, except the channel width is quantized. The benefits in chip scalability are minimal, but compromise between low voltage/high speed operation and low power dissipation/noise interference is big problem. Physical implementation is in planar manner, and the channels of active devices are in same or parallel planes with metal interconnect tracks, resistors and capacitors. The influence of parasitic effects, such as cross talk, electro migration, voltage drop, gate noise is essential problem. Also floor plan, power supply, matching, layout design, physical design verification, DFM became very complicate in special for System on the Chip (SoC). For example: ˜50,000 rules in Design Rules Check (DRC) deck for 14 nm process, and ˜1,000 rules for 65 nm. The performance of the entire design hinges on the Process Design Kits (PDK), CAD tools, layout designer's qualification, and technological achievements in gate formation. The FinFET technology, CAD tools, PDK and layout design for 20, 16, 14, 10, 6 nm nodes are very expensive. The FinFET chips are not so good for space applications, because the probability of radiation impact is high.

In [2] is patented the idea to create vertical CMOS devices based on researches of carbon nano tube vertical field effect transistor, which can be take in consideration as a prototype for present disclosure (FIG. 4.c). However, this technology does not allow implementation of bipolar transistors in one chip too, and is expected to be more expensive than FinFET technology.

The achievements in anisotropic etching of Si (111) and result related to fin, pyramid, pencil and con textures are described in [11, 12, 13, 14, 15] (FIG. 4.a.)

### SUMMARY OF THE INVENTION

The present invention relates to vertically integrated, quantized semiconductor sharp devices, and fabrication methods thereof; utilizing the conventional BiCMOS process, adjusted to quasi-planar structure types. More particularly, the invention relates to FET with sharp drain and BIT with sharp emitter implemented into multiple identical single crystalline semiconductor pyramids, placed in-situ directly on the surface of diffusion regions with a high dopant level of a first and second conductivity type, formed respectively in the wells. The devices' gate and base structures are formed at a level of 35-45 nm below the top of the pyramid. The bottom region of the pyramids contains the collector/source structures, while the top region of the pyramids contains the emitter/drain structures. The pyramids are created by selective epitaxial growth of low dopant Si (100) into vertical cavity, formed in oxide layer. The dimensions of each pyramid structure are around 60×60 nm (base), 120 nm (height), and a 120 nm pitch. After growing, a COR pre-clean is performed and the recesses are filled by epitaxial growing of a low dopant layer of a same conductivity type and dopant level as COR. The BJT type pyramid structures are selectively high doped and thus form collector structures of the first and second conductivity type. The BJT base structure is formed by selective epitaxial growth of Si—SiₓGe₁₋ₓ—Si with opposite conductivity type as COR, and interconnected by a horizontal polysilicon grid. The self-aligned gates for the FET are obtained through horizontally deposited respective layers of: nitride, high-k insulator, polysilicon, high-k insulator, and nitride; creating a grid of “bridged” gates. The oxide under the gate bridge is etched, then the FET type pyramid structures are selectively high doped forming a gate structure of the first and second conductivity type. The plurality of FET type pyramids is interconnected via a common gate, source, and drain; forming a single quantized transistor, wherein the length of transistors is a thickness of a deposited poly layer, and is not critical to lithography restrictions.

### BRIEF DESCRIPTION OF THE DRAWINGS

FIG. 1. is a cross section diagram and planar view illustrating the embodiment of BICMOS quantized devices—a vertical transistor such as bipolar junction transistor (BJT) or field effect transistor (FET) with sharp emitter or drain.

FIG. 2.a. is a cross section diagram illustrating an embodiment of a vertical n-p-n structure such as bipolar junction transistor (BJT) or heterojunction transistor (HBT) with sharp emitter.

FIG. 2.b. is a cross section diagram illustrating an embodiment of a vertical p-n-p BJT with sharp emitter.

FIG. 2.c. is a cross section diagram illustrating an embodiment of a vertical n-FET with sharp drain.

FIG. 2.d. is a cross section diagram illustrating an embodiment of a vertical p-FET with sharp drain.

FIG. 3a. is a part of flow diagram illustrating an embodiment of a method of forming a transistor structures such as the structure illustrated in FIG. 2.a-d. Particularly on this stage are partial created collector and source structures, and are formed p-type and n-type silicon pyramids for BJT and FET.

FIG. 3.b. is a part of flow diagram illustrating an embodiment of a method of forming a transistor structures such as the structure illustrated in FIG. 2.a-g. On this stage are created thin n-type epitaxial layer for n-type pyramids, collector structure and p-type base structure on level (I) for n-p-n BJT.

FIG. 3.c. is a part of flow diagram illustrating an embodiment of a method of forming a transistor structures such as the structure illustrated in FIG. 2.a-g. On this stage are created thin p-type epitaxial layer for p-type pyramids, collector structure and n-type base structure on level (I) for p-n-p BJT.

FIG. 3.d. is a part of flow diagram illustrating an embodiment of a method of forming a transistor structures such as the structure illustrated in FIG. 2.a-g. On this stage are created on level (II) and (III) horizontal poly structures connected to BJT bases, and gate structures for FET. Also is removed SiO₂ for n-FET, and is created first gate bridge.

FIG. 3. e. is a part of flow diagram illustrating an embodiment of a method of forming a transistor structures such as the structure illustrated in FIG. 2.a-g. On this stage are created gate structures for n-FET and is removed SiO₂ for p-FET second gate bridge.

FIG. 3.f. is a part of flow diagram illustrating an embodiment of a method of forming a transistor structures such as the structure illustrated in FIG. 2.a-g. On this stage are created gate structures for p-FET, and oxidation is provided.

FIG. 3.g. is a part of flow diagram illustrating an embodiment of a method of forming a transistor structures such as the structure illustrated in FIG. 2.a-g. On this stage are created p-type emitter structure for p-n-p BJT and p-type source structure for p-FET.

FIG. 3.h. is a part of flow diagram illustrating an embodiment of a method of forming a transistor structures such as the structure illustrated in FIG. 2.a-g. On this stage are created n-type emitter structure for n-p-n BJT and n-type source structure for n-FET.

FIG. 3.i. illustrates created and interconnected n-p-n BJT, p-n-p BJT, n-FET and p-FET transistors with sharp emitter/drain.

FIG. 4.a. shows a cross-section diagram of prior art applications related to fin textured silicon (100), pencil textured silicon (111), pyramid textured silicon (111), and con textured silicon

FIG. 4.b. shows the key of prior art applications related to finFET technology, took in consideration as analog for present disclosure.

FIG. 4.c. shows the perspective view of prior art application related to carbon nano-tubes multi gate FET, took in consideration as prototype for present disclosure.

FIG. 4.d. shows some basic application related to sharp fluid output and sharp cathode configuration, which allow achieving the same effect for lower pressure/voltage

### DETAILED DESCRIPTION OF THE PREFERED EMBODIMENTS

The embodiments herein will be better understood from the following detailed description that references the drawings, which are not necessarily drawn to scale. In the description of the invention, “n”, “n+”, “N”, “N+” and “p”, “p+”, “P”, and “P+” are used to define relative dopant types and concentrations. FET is used interchangeably with “field-effect transistor”, or “metal-oxide transistor”. BJT is used interchangeably with “bipolar junction transistor” or “bipolar heterojunction transistor”. COR is used interchangeably with “Composite Object Reference structure”. CMP is used interchangeable with “Chemical-Mechanical Polishing/Planarization”. RIE is used interchangeable with “Reactive Ion Etching”.

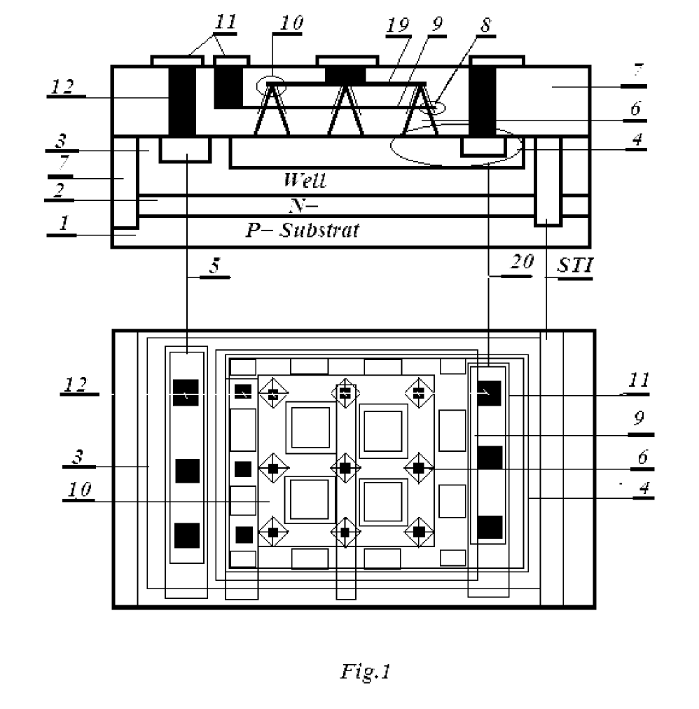

In reference to the drawings, FIG. 1. shows the general concept of the present invention. A cross section diagram and planar view illustrate a first preferred embodiment of a vertical quantized transistor such as a BJT and FET with a sharp emitter or drain fabricated, utilizing the conventional BiCMOS process, which is adjusted to the implementation of specific quasi-planar structures. It is a portion of a semiconductor chip that includes a monocrystalline, P+ type Si (100) substrate [1], first Si (100) epitaxial layer on the substrate [2], second Si (100) epitaxial layer [3], with N and P wells insulated by SiO₂ regions [7], according to the state-of-the-art shallow trench insulation (STI) process, large sub-collector and sub-source diffusion structures [4] with opposite conductivity types as well, tap diffusion regions inside of the well [5], connection to the source or collector structures [20], base or gate structures [8], base or gate grid [9], emitter or drain structure [10], emitter or drain grid [19], contact [12], metal 1 layer portions [11], and single crystalline silicon (111) pyramids [6], created in SiO₂ cavities by epitaxial growth of Si (100). Pre-cleaning and sharpening is performed, using reactive ion etching (RIE), and the recesses are filled by the epitaxial growth of a low dopant layer of the same conductivity type and dopant level as COR.

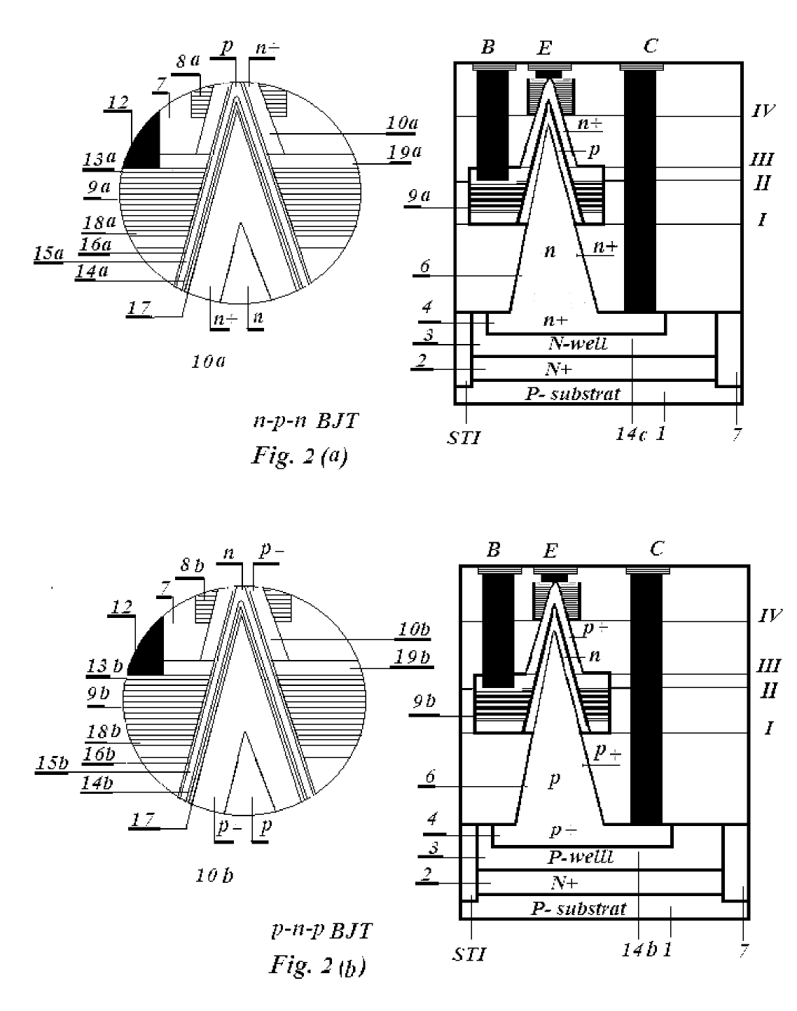

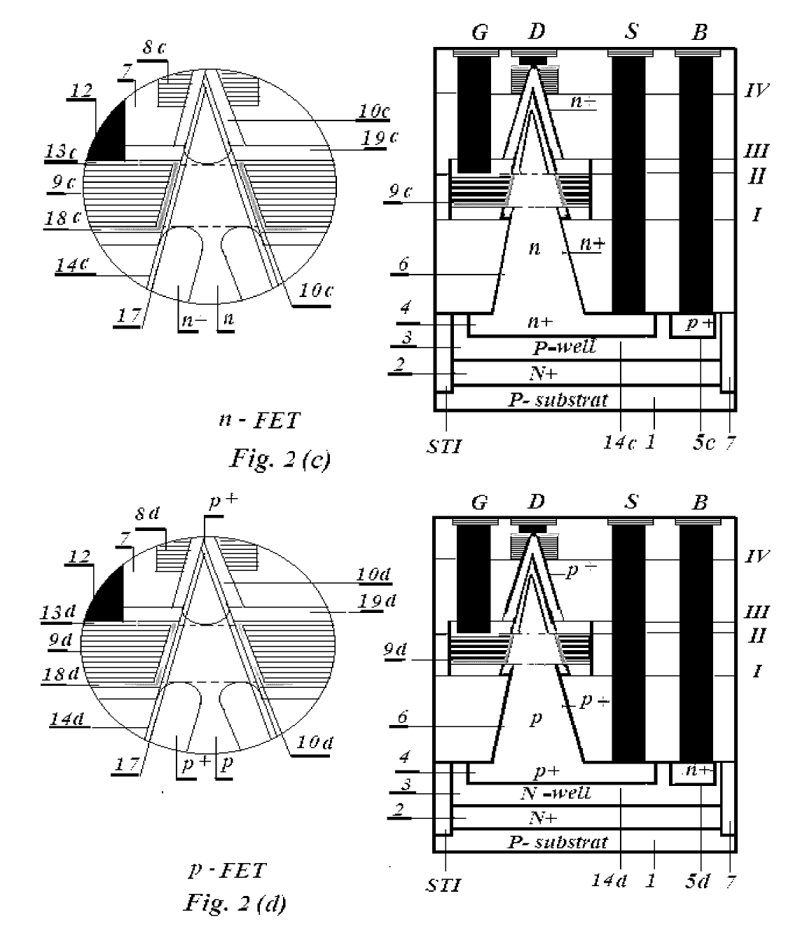

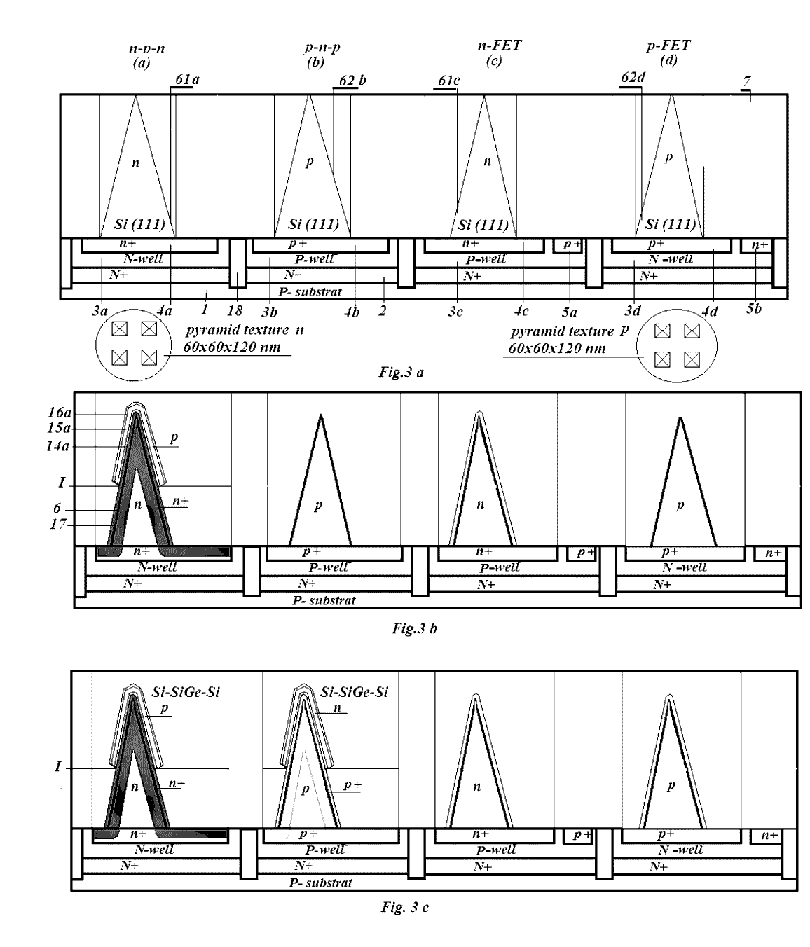

More details relating to the n-p-n BJT is shown in FIG. 2(a), wherein SiO₂ is removed from regions of the n-p-n transistor, and n-type pyramids and collector diffusion regions are highly doped with an n+ type of implant, forming enriched peripheral conductivity of pyramids which in turn minimizes collector resistance. Then, SiO₂ is deposited on level (I) 40-50 nm below the upper tips of the pyramids. After that, the surface of the pyramids [17] is cleaned, using an RIE process. The base structure is formed by the epitaxial growth of p-type Si—SiGe—Si (100) (Si [14b] 0.1-0.2 nm, SiGe [15b] 5-10 nm, and Si [16b] 0.2-0.4 nm). The base grid is formed by the selective horizontal formation of a polysilicon layer [9a], coated on both sides by an SiO₂ layer [18a], followed by an Si₃N₄ layer [19] (also on both sides). The connection of polysilicon to the base structure is obtained as a result of polysilicon growth of SiO₂ on an insulator and as Si on Si—SiGe—Si structure. After deposition of the first and second nitride layers and before the emitter structure formation, an RIE pre-clean of the pyramids is performed on levels (I) and (III) respectively in order to remove the nitride layer from the sloped sides of the pyramids before the deposition of a polysilicon layer and a nitride layer on the sloped sides of the pyramids. Then SiO₂ is deposited on level (III) and an n+ type emitter structure [10a] is formed by epitaxial growth of Si (100) on the p-type base structure pyramid (thickness range 20-30 nm) with a higher concentration of the same dopant materials (range 10-100%) as the pyramid COR. Then SiO₂ is deposited on level (IV) forming a polysilicon connection to the emitter [8a]. Connection [12] of polysilicon base [9a] and polysilicon emitter [10a] are obtained by etching SiO₂ and Si₃N₄ and using respectively p-type or n-type silicide layers.

More details relating to p-n-p BJT are shown in FIG. 2(b). SiO₂ is removed from the p-n-p transistor regions. P-type pyramids and collector diffusion regions are highly doped with a p+ type of implant, forming an enriched peripheral conductivity of pyramids, in turn minimizing collector resistance, and achieving a sharp configuration of collectors. Then, SiO₂ is deposited on level (I), 40-50 nm below the tips of the pyramids, forming an n-type base structure by epitaxial growth of n-type Si—SiGe—Si (100) layers (Si [14b] 0.1-0.2 nm, SiGe [15b] 5-10 nm, and Si [16b] 0.2-0.4 nm). The base grid is formed by the selective horizontal formation of a polysilicon layer [9a], coated on both sides by an SiO₂ layer [18a], followed by an Si₃N₄ layer [19] (also on both sides).

Then SiO₂ is deposited on level (III) and p+ type emitter structure [10b] is formed by epitaxial growth of Si (100) on the n-type base structure. SiO₂ is deposited on level (IV), where a polysilicon connection to the emitter [8b] is created. Connection of polysilicon base grid and polysilicon emitter grid are obtained by the etching of SiO₂ and Si₃N₄ and using respective n-type and p-type silicide layers.

More details, relating to n-FET, are shown in FIG. 2(c), wherein SiO₂ is deposited on level (I) 40-50 nm below the upper tips of the pyramids. The gate structure is formed by selective horizontal deposition of S₃N₄, high-k insulator, polysilicon, high-k insulator and Si₃N₄ layers [19c], [18c], [9c]. After the deposition of the first and second nitride layers, an RIE pre-clean of the pyramids is performed on levels (I) and (III) in order to remove the nitride layer from the sloped sides of the pyramids before the deposition of a first high-k insulator layer, and the nitride and high-k insulator layers on the sloped sides of pyramids, all before the formation of the drain structure. The connection of polysilicon to the gate is obtained as a result of the high-k insulator layer being deposited in T-mode, forming a horizontal thin high-k insulator layer and gate on the sloped sides of the pyramids. The thickness of the polysilicon layer determines the length of gate. The gate structure is formed as a gate bridge with open windows (about 80×80 nm), placed on the same coordinates as tap structures in the bottom regions of the pyramids. After that, oxide is removed from all regions of n-FET and the gate bridge serves as a mask for selective implantation of high dopant impurity of the same conductivity as COR in turn creating self-aligned gates.

More details, relating to p-FET are shown in FIG. 2(d), wherein SiO₂ is deposited on level (I), 40-50 nm below the tips of the pyramids. The gate structure is formed by selective horizontal deposition of S₃N₄, high-k insulator, polysilicon, high-k insulator and Si₃N₄ layers [19d], [18d], [9d]. The process of creating the source structure, the self-aligned gate bridge, and the emitter structure is similar to the previously described n-FET in FIG. 2(c), except the conductivity of the diffusion regions and the conductivity of the epitaxial layer is opposite.

The fabrication method of the presently preferred embodiments is described below. It should be appreciated however, that the present invention provides many applicable inventive concepts that can be embodied in a wide variety of semiconductor fabrication contexts. The specific embodiments discussed are merely illustrative of specific ways to make and use the invention, and do not limit the scope of the invention. Description of well-known components and processing techniques are omitted so as to not unnecessarily obscure the embodiments of the invention.

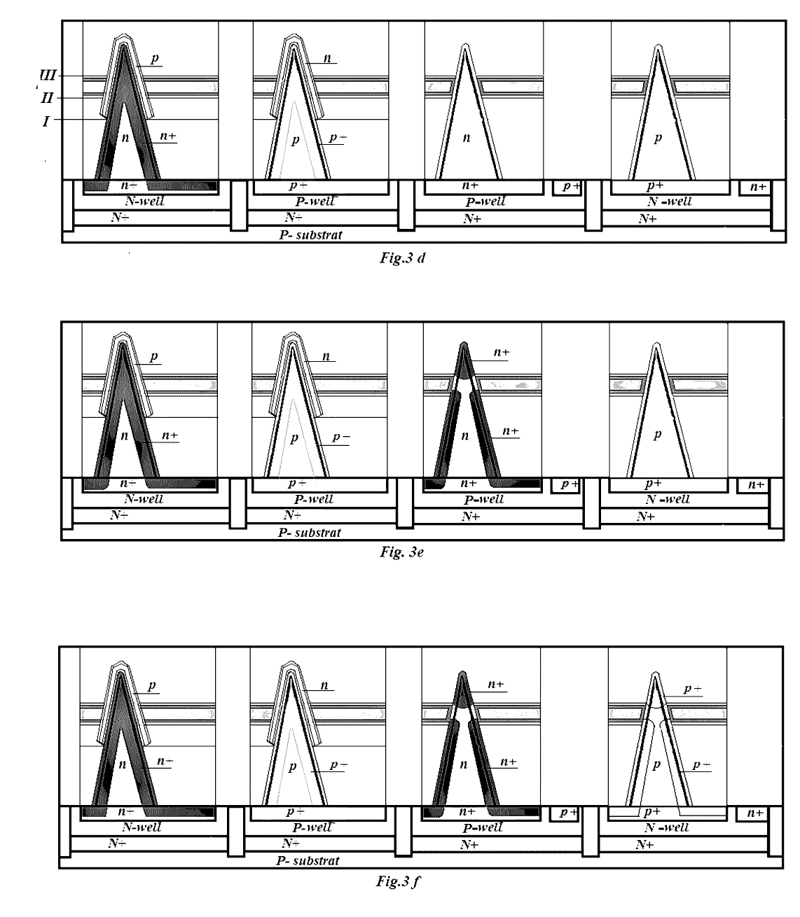

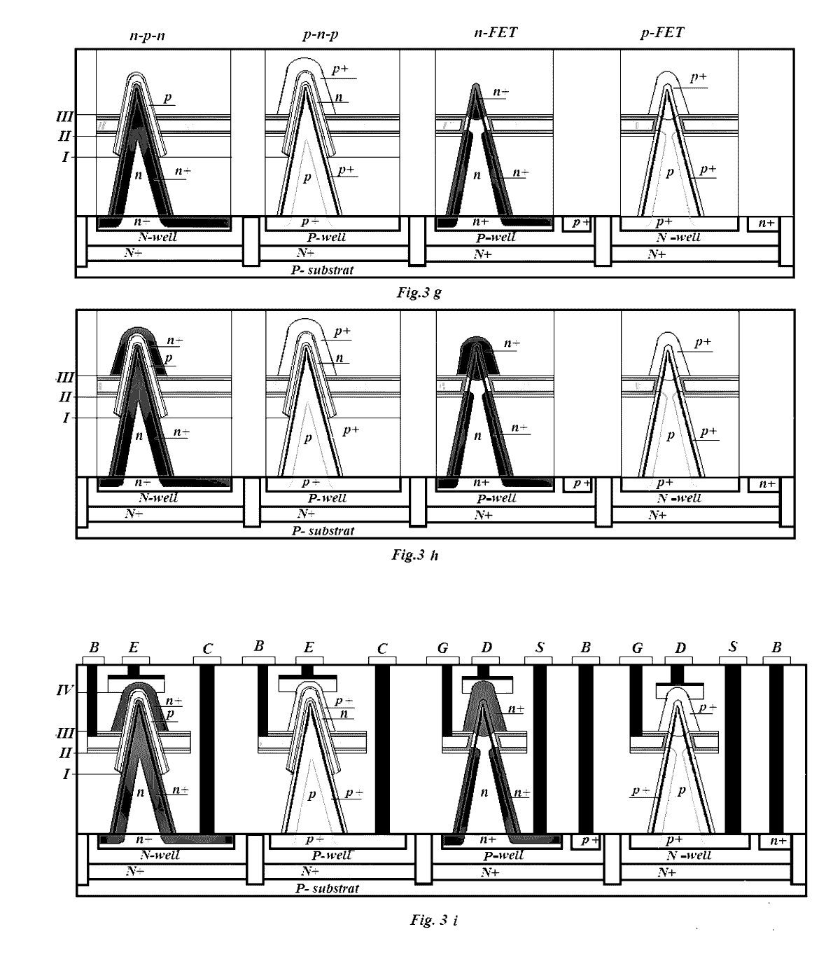

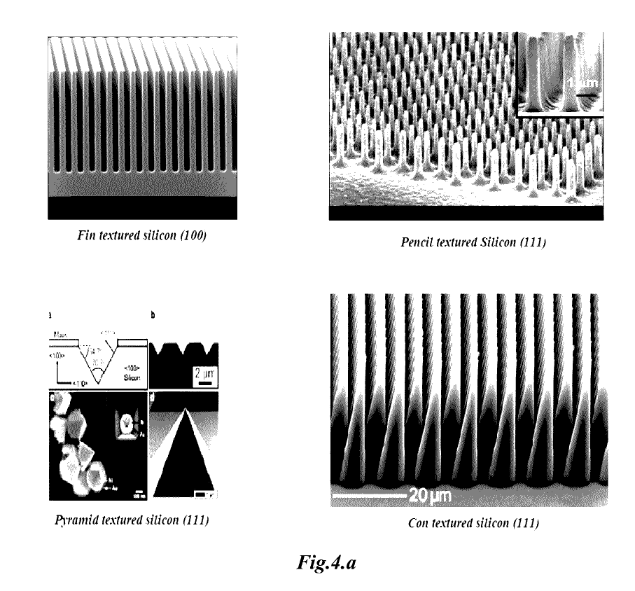

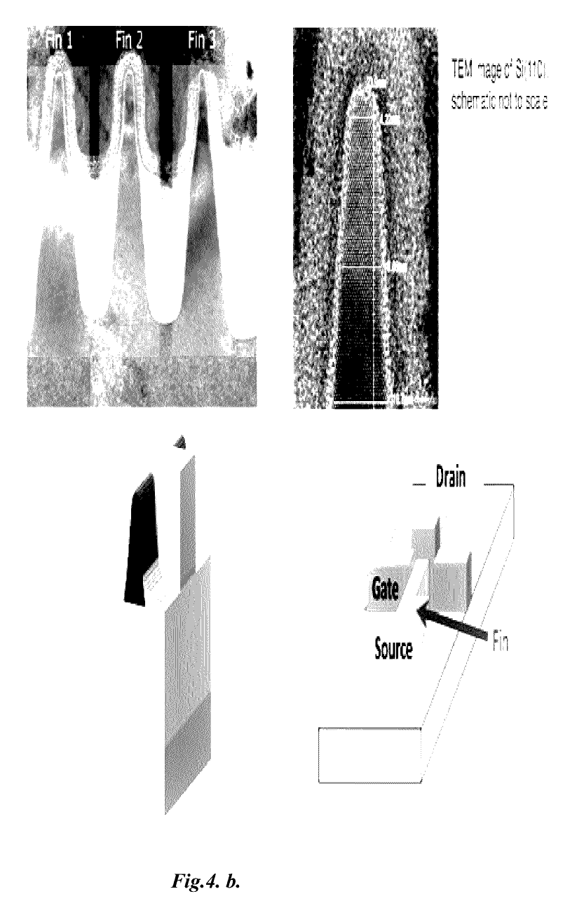

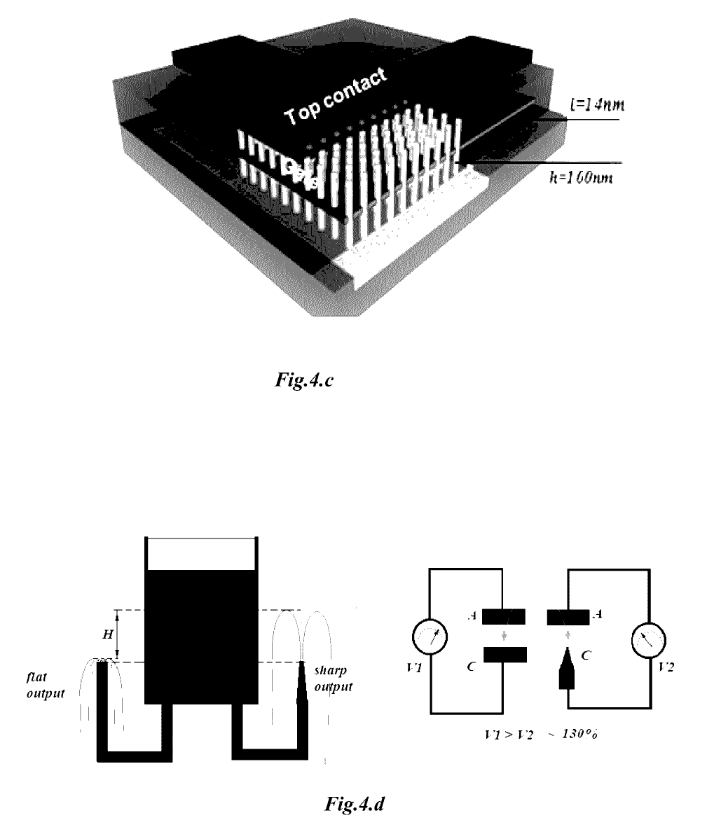

FIG. 3a-i shows the basic fabrication process flow of an n-p-n BJT(a), p-n-p BJT(b), n-FET(c) and p-FET(d) described by the following steps:

Step 1(FIG. 3a) starts with a P+ type silicon substrate [1], N+ first Si (100) epitaxial layer on the substrate [2], and a second Si (100) epitaxial layer [3], which represent the active area for building BJT and FET with sharp emitter/drain. The active areas are patterned by first depositing of thin oxide and nitride. A photoresist is deposited and patterned on the top of the nitride. This leads to the following consecutive steps: Creation of STI regions [18] using state-of-the-art STI and CMP processing. Creation of N+ wells [3a], [3d], and P+ wells [3b], [3c]. Creation of N+ wells [3a], [3d], and P+ wells [3b], [3c] using a conventional twin well process. Creation of n+ large diffusion regions [4a], [4c], and p+ diffusion regions [4b], [4d] using a conventional BiCMOS process. Creation of p+ tap [5a] for n-FET and n+ tap [5b] for p-FET. Creation of a Si₃N₄ hard mask on Si (100) substrate, with a 60×60×120 nm segment array, with a 120 nm pitch. Deposition of SiO₂ (thickness of 105-110 nm), CMP, and planarization. Etching of Si₃N₄. Selective epitaxial growth of Si (100) of first and second conductivity types in the opened SiO₂ cavities, wherein the wafer is placed face down in the reactor, parallel to the direction of the gaseous flow of SiCl₄. Low dose energy RIE pre clean and sharpening is provided. Opening n-p-n BJT(a), p-n-p BJT(b), n-FET(c) and p-FET(d) pyramids, followed by a wet etching. SiO₂ deposition.

Step 2 (FIG. 3b) start with opening (a) and (c) n-type pyramids, pre-clean and an epitaxial deposition of a Si n-type layer (thickness of 0.1-0.2 nm) to fill the recesses on the sloped sides of the pyramids.

This leads to the following consecutive steps: SiO₂ deposition. Opening n-type pyramids [6] of region n-p-n BJT(a) including n+ diffusion regions [4a]. High level n+ implantation and formation of a sharp collector [17] for n-p-n BJT. SiO₂ deposition on level (I), pre-clean and epitaxial deposition of a p-type base structure Si—SiGe'Si (100) layers (Si [14b] 0.1-0.2 nm, SiGe [15b] 5-10 nm, and Si [16b] 0.2-0.4 nm). SiO₂ deposition.

Step 3 (FIG. 3c) start with opening the regions of p-n-p BJT(b) and p-FET(d). This leads to the following consecutive steps: Pre-clean of p-type pyramids and epitaxial deposition of a Si p-type layer (0.1-0.2 nm) to fill the recesses on the sloped sides of the pyramids. SiO₂ deposition. Opening p-type pyramids [6] of region p-n-p BJT(b) including p+ diffusion regions [4b]. High level p+ implantation and forming a sharp collector for p-n-p BJT. SiO₂ deposition on level (I), pre-clean and epitaxial deposition of a n-type base structure Si—SiGe—Si (Si [14b] 0.1-0.2 nm, SiGe [15b] 5-10 nm, and Si [16b] 0.2-0.4 nm). SiO₂ deposition.

Step 4 (FIG. 3d) start with opening all pyramids of regions n-p-n BJT(a), p-n-p BJT(b), n-FET(c) and p-FET(d) on level (II). This leads to the following consecutive steps: Creation of a nitride grid through deposition and patterning, wherein the grid window size is around 80×80 nm each. SiO₂ deposition on the top level of the pyramids. Opening n-p-n BJT(a) pyramids on level of nitride grid and RIE pre-cleaning from level (II). Creation of a p-polysilicon layer through deposition and patterning, wherein the window size is around 80×80 nm (thickness range 10-20 nm), forming electrode to p-type base with enclosure of COR greater than 20 nm. RIE pre-cleaning from level (III). Creation of a nitride grid through deposition and patterning, wherein the window size is around 80×80 nm. RIE pre-cleaning from level (III) and SiO₂ deposition at the top level of the pyramids. Opening p-n-p BJT(b) pyramids at the level of the nitride grid and RIE pre-cleaning from level (II). Creation of a n-polysilicon layer through deposition and patterning, wherein the window size is around 80×80 nm (thickness range 10-20 nm), forming electrode to n-type base with enclosure of COR greater than 20 nm. RIE pre-cleaning from level (III). Creation of a second nitride grid through deposition and patterning, wherein the window size is around 80×80 nm. RIE pre-cleaning from level (III) and SiO₂ deposition on the top level of the pyramids. Opening n-FET(c) and p-FET(d) pyramids at the level of the nitride grid and RIE pre-cleaning from level (II). Creation of a high-k insulator layer in T-mode through deposition and patterning, wherein the window size is around 80×80 nm (thickness range 2-10 nm), forming a gate on the sloped sides of the pyramids, with horizontal enclosure of COR greater than 20 nm. Creation of a polysilicon gate electrode (thickness range 2-20 nm which determines the length of gate) through deposition and patterning, wherein the horizontal enclosure of COR greater than 20 nm. Creation of a second high-k insulator layer in T-mode through deposition and patterning, wherein the window size is around 80×80 nm (thickness range 2-10 nm). RIE pre-cleaning from the level (III). Creation of a second nitride grid through deposition and patterning, wherein the window size is around 80×80 nm. RIE pre-cleaning from level (III) and SiO₂ deposition on the top level of the pyramids. All SiO₂ removal from n-FET(c) regions and opening of the reinforced n-FET gate bridge, wherein the open window size is around 80×80 nm and are placed on same coordinates as p+ taps. High level of n+ implantation and formation of high dopant source and drain structures, wherein the self-aligned gate has a low dopant level. For DRAM structures, the capacitor [22] is created in this step, according to second preferred embodiment of the present invention (FIG. 2e). The capacitor is formed immediately after opening the reinforced n-FET gate bridge by deposition of a high-k insulated layer on an opened source structure (first electrode) and a poly layer (second electrode connected to the tap). The poly grid bridge is used as a mask in lithography processing for opening a high-k insulated layer on the p+ taps and the deposition of a poly layer with the same conductivity type as the p+ tap. The value of the under-bridge capacitor can be adjusted by sizing the area of the horizontal diffusion region of the source. Deposition of a high-k insulating layer and deposition of a high-k capacitor includes selecting a high-k material from the group of materials consisting of HfO₂, ZrO₂ and HfZrOx.

Step 5 (FIG. 3e) start with removing all SiO₂ from p-FET(d) regions and opening the reinforced p-FET gate bridge, wherein the open window size is around 80×80 nm and are placed on same coordinates as n+ taps. High level of p+ implantation is provided for formation of high dopant source and drain structures; wherein a self-aligned gate has a low dopant level.

Step 6 (FIG. 3f) start with SiO₂ deposition on the upper level of the pyramids for p-FET(d) regions. On this step the collector and base structures for BJT are done. Also the creation of source and gate structures for FET is now completed.

Step 7 (FIG. 3g) start with opening regions p-n-p BJT(b) and p-FET(d) on level (III). RIE pre-cleaning of opened parts of COR is provided, and epitaxial silicon p+ layer is grown for creation of emitter structures for p-n-p BJT and source structures for p-FET. The concentration of p+ dopant is 10-100% higher in comparison to the concentration of the collector/source structures.

Step 8 (FIG. 3h) start with opening regions n-p-n BJT(a) and n-FET(c) on level (III). RIE pre-cleaning of opened parts of COR is provided, and epitaxial silicon n+ layer is grown for the creation of emitter structures for n-p-n BJT and source structures for n-FET. The concentration of n+ dopant is 10-100% higher in comparison to the concentration of the collector/source structures.

Step 9 (FIG. 3i) start with opening regions n-p-n BJT(a) and n-FET(c) on level (IV). This leads to the following consecutive steps: Deposition of an n-type polysilicon layer. Patterning of emitter grid for n-p-n BJT and similar drain grid for n-FET. SiO₂ deposition at a thickness of 10-50 nm on the upper level of the pyramids. Opening regions p-n-p BJT (b) and p-FET(d) on level (IV). Deposition of a p-type polysilicon layer. Patterning of polysilicon emitter grid for p-n-p BJT and similar drain grid for p-FET. SiO₂ deposition at a thickness of 10-50 nm in the upper level of the pyramids.

1. A vertical integrated quantized semiconductor sharp transistor comprising:
a silicon substrate of a first conductivity type;
a first silicon epitaxial layer of a second conductivity type above the substrate;
a second silicon epitaxial layer of a first conductivity type;
a diffusion region of a first or second conductivity type, said well, implemented in an epitaxial layer and insulated by SiO₂ regions said shallow tranche insulation (STI), according to the conventional CMOS twin well process;
a large diffusion region of a second or first conductivity type, and at least one diffusion region of the opposite conductivity type, said tap implemented separate inside of the well;
a plurality of identical semiconductor pyramid structures, placed in-situ directly on the large diffusion region of the well, creating said pyramid texture;
wherein the pyramids are obtained by selective epitaxial growth of low dopant Si (100) into vertical oxide cavities, having the first and second conductivity type;
a first structure, said base or gate intrinsic structure of a first or second conductivity type formed on the sloped side of the pyramid, coupled together by a horizontal grid of a polysilicon layer, and interconnected by contacts;
wherein a polysilicon layer contains silicide and is covered on both sides by a high-k insulator and nitride layers;
a second structure, said emitter or drain intrinsic structure of a second or first conductivity type, formed on the top of each pyramid, coupled together by the second poly grid layer with contacts from emitter or drain to the metal 1 layer;
a third structure, said collector or source structure of a second or first connectivity type, formed on the bottom region of the pyramids, coupled together by a large diffusion region with contacts from the collector or source to metal 1 layer;
a tap connection to the power supply or ground by contacts and metal 1 layer.

2. A BJT base intrinsic structure on the sloped side of the silicon pyramid, placed below the top tip (range 40-50 nm), as claimed in claim 1, comprising:
a first epitaxial silicon layer on the surface of the pyramid of a second or first conductivity type (thickness range 0.1-0.2 nm);
a second silicon-germanium epitaxial layer of a second or first conductivity type on the first silicon layer (thickness range 5-10 nm);
a third epitaxial silicon layer of a second or first conductivity type on the silicon-germanium layer (thickness range 0.2-0.4 nm);
a polysilicon layer grid of a second or first conductivity type, formed in result that SiₓGe₁₋ₓ grows as a crystal on silicon, and as polycrystalline on oxide;
a silicide of a second or first conductivity type, for example TiSi₂, layer on the silicon zone and poly-layer;
a contacts to the polysilicon layer and the metal layer;

[symbol]

3. A FET gate intrinsic structure on the sloped side of the silicon pyramid, placed horizontally on the SiO₂ substrate, below the tips of the pyramids (range 30-40 nm), as claimed in claim 1, comprising:
an epitaxial silicon layer of a second or first conductivity type on the surface of the pyramid (thickness range 0.1-0.2 nm);
a bottom nitride layer grid (open size about 80×80 nm, pitch 120 nm, thickness range 5-20 nm, enclosure of silicon pyramids 5-40 nm, enclosure of quantized transistor area 40-60 nm);
a first T-mode deposited high-k insulator grid (open size—about 80×80 nm, thickness range 2-10 nm), formed directly on thin epitaxial layer on sloped side of pyramid, and on bottom nitride layer grid;
a deposited polysilicon layer grid (open size—about 80×80 nm, thickness range 2-20 nm), placed directly on a first T-mode deposited high-k insulator grid;
a second T-mode deposited portion of high-k insulator grid (open size—about 80×80 nm, thickness range 2-10 nm), placed on the polysilicon grid;
a top deposited nitride layer grid (open size—about 80×80 nm, thickness range 5-20 nm), placed on high-k insulator grid;
a gate bridge structure, formed in result of full etch of SiO₂ under the bottom nitride grid;
a high doped source and drain regions of pyramids obtained in result of diffusion of a same kind of impurity as pyramids COR;
a contact to polysilicon grid and metal 1 layer;

[symbol]

4. An emitter or drain intrinsic structure of a second or first conductivity type formed on top of the pyramids, starting at a level of 15-20 nm below of the pyramid tips, as claimed in claim 1, comprising:
an epitaxial high dopant growth layer on the open top surface of the pyramid (thickness range 20-30 nm) with a higher concentration of the same dopant materials (range 10-100%) as the pyramid COR;
a polysilicon layer grid (open size—about 80 nm, thickness range 30-40 nm, enclosure of silicon pyramid 5-20 nm, enclosure of quantized transistor area 50-70 um), formed in result of using chemical vapor deposition, lithography processing, and deposition of silicide (TiSi₂) with the same type of conductivity as the pyramid COR;
a contact to polysilicon and metal 1 layer.

5. A n-FET with sharp drain, as claimed in claim 1, comprising:
a n type gate structure, n+ type source structure, and a n+ type drain structure;
wherein the first conductivity is p type, second conductivity is n type, and a p+ tap is connected to the ground.

6. A p-FET with sharp drain, as claimed in claim 1, comprising:
a p type gate structure, p+ type source structure, and a p+ type drain structure;
wherein the first conductivity is p type, second conductivity is n type, and a n+ tap is connected to the power supply.

7. A n-p-n BJT with sharp emitter, as claimed in claim 1, comprising:
a p type base structure, n+ type collector structure and n+ type emitter structure;
wherein the first conductivity is p-type, and the second conductivity is n+ type.

8. A p-n-p BJT with a sharp emitter, as claimed in claim 1, comprising:
a n-type base structure, p+ type emitter structure, and p+ type collector structure;
wherein the first conductivity is p-type, and the second conductivity is n-type.

9. The method of creation a silicon (111) pyramid structure, as claimed in claim 1 comprising:
creation of a Si₃N₄ hard mask on Si (100) substrate, with an array of segments of 60×60×120 nm, with a 120 nm pitch;
deposition of SiO₂ and chemical-mechanical polish and planarization;
etching of Si₃N₄;
selective epitaxial growth of Si (100) of first and second conductivity types in the opened SiO₂ cavities;
wherein the wafer is placed face down in the reactor, parallel to the direction of the gaseous flow of SiCl₄;
low dose energy RIE pre clean and sharpening of pyramids is provided.

10. The method related to claims 1 and 3 wherein deposition a high-k insulating layer includes selecting a high-k material from the group of materials consisting of HfO₂, ZrO₂ and HfZrOx.
